(19) United States
(12) Patent Application Publication
(10) Pub. No.: US 2002/0068467 A1
(43) Pub. Date: Jun. 6, 2002

(54) Method of fabricating PE-SiON film

(76) Inventors: Woo-Chan Jung, Seoul (KR); Jin-Ho Jeon, Seoul (KR); Jeon-Sig Lim, Kyonggi-do (KR); Jong-Seung Yi, Suwon-city (KR); Kyung-Tae Kim, Kangwon-do (KR)

Correspondence Address: JONES VOLENTINE, P.L.L.C., SUITE 150, 12200 SUNRISE VALLEY DRIVE, RESTON, VA, 20191, US

(21) Appl. No.: 09/885,090

(22) Filed: Jun. 21, 2001

(30) Foreign Application Priority Data
Dec. 5, 2000 (KR) 2000-73191

(51) Int. Cl. H01L 21/00; H01L 21/31; H01L 21/469

(52) U.S. Cl. 438/786

(57) ABSTRACT

A method of fabricating a PE-SiON film includes forming a PE-SiON film by turning on a high frequency radio frequency (HF RF) power in the chamber after a plurality of reaction gases SiH₄, N₂, NH₃, N₂O have simultaneously flown into a chamber without proceeding a bypass process of SiH₄.

### CROSS-REFERENCE TO RELATED APPLICATIONS

The present application claims priority under 35 U.S.C. §119 to Korean Patent Application No. 2000-73191 filed on Dec. 5, 2000, the entire contents of which are hereby incorporated by reference for all purposes.

### BACKGROUND OF THE INVENTION

1. Field of the Invention

The present invention relates to a method of fabricating a PE-SiON film for anti-reflective coating (ARC), more particularly to a method in which the turn-on point of radio frequency power and SiH₄ is changed, thereby remarkably reducing the generation of particles.

2. Description of the Related Art

The more a semiconductor device is highly integrated, the more an abnormal exposure of a photoresist due to diffuse reflection of light may cause a great defect in products. An anti-reflective coating film (ARC) can control the diffuse reflection of light. A PE-SiON film has been widely used as an ARC film.

The PE-SiON film is commonly fabricated by a process of plasma enhanced chemical vapor deposition through the reaction of gas. One of the greatest problems in the process is the generation of a byproduct by which the film characteristics is deteriorated or remarkably damaged. The byproduct is generated as a particle type or a film having a different composition from that of the main product and determined by mutual reaction of the thermodynamic factors such as temperature, pressure, radio frequency (RF) power, reaction gas concentration, carrier gas concentration, etc. Accordingly, studying the thermodynamic factors is essential to control the generation of a byproduct that causes the deterioration of the film characteristics.

FIG. 1 is a graph showing a conventional method of forming the PE-SiON film. In the drawing, the horizontal axis indicates time in seconds, the vertical axis indicates the reaction gases flowing into a chamber, and reference symbol T indicates the starting point at which a main deposition process of the PE-SiON film starts.

The graph shown in FIG. 1 explains the deposition method of forming PE-SiON film as follows. All the reaction gases N₂, NH₃, N₂O other than the gas SiH₄ flow into the chamber sixteen seconds before the main deposition starting point T indicated as “T−16”. The gas SiH₄ flows into the chamber after having bypassed the chamber for sixteen seconds. Accordingly, the gas SiH₄ flows into the chamber sixteen seconds after the gases N₂, NH₃, N₂O start to be supplied. That is, the gas SiH₄ starts to flow into the chamber at the main deposition starting point T. The high frequency RF is supplied to the chamber one second before the gas SiH₄ flows into the chamber. The main deposition process for forming the PE-SiON film starts at the turn-on point T at which the gas SiH₄ is supplied into the chamber. The main deposition if performed for thirty-four to forty seconds after the main deposition starting point T, illustrated by “T+(34˜40)”. As a result, the PE-SiON film is formed. The chemical formula is as follows:

SiH₄+N₂+NH₃+N₂→SiO_{X}N_{Y} (1)

However, when the PE-SiON film is formed in such a conventional deposition method, there is a problem that the gas NH₃ in the chamber abnormally reacts during seconds from the time the RF is supplied until the SiH₄ is introduced to the chamber. This reaction generates the particle sources because the RF power is turned-on before the gas SiH₄ flows into the chamber.

The particles generated in such an environmental are on the order of sub micron in size. Since it is not easy to detect a particle smaller than 1 μm in a particle detecting step, the particles remain in the chamber. Such a particle size in the following process causes severe defects such as bridges between conductive patterns, abnormal patterns, etc. when a following patterning process is proceeded while the particles remain.

### SUMMARY OF THE INVENTION

The present invention is therefore directed to a method of forming a PE-SiON film that substantially overcomes one or more of the problems due to the limitations and disadvantages of the related art.

It is an object of the present invention to provide a method of fabricating a PESiON film by which a process for bypassing SiH₄ gas is omitted during the formation of PE-SiON film for ARC by a PECVD process and a gas SiH₄ flows into a chamber before RF power is turned-on. This modification prevents the abnormal reaction and minimizes the generation of particles.

In order to accomplish the object, a method of fabricating a PE-SiON film according to the present invention include simultaneously flowing a plurality of reaction gases SiH₄, N₂, NH3, N₂O flowing into a chamber and turning on a high frequency radio frequency (HF RF) power in the chamber, thereby forming a PE-SiON film.

The HF RF power may be turned-on three seconds after the plurality of reaction gases start to flow, and the PE-SiON film is formed during 34 to 40 seconds after the RF power is turned-on.

When the PE-SiON film is formed in such a way in accordance with the present invention, since the RF power is turned-on under the state that the gas SiH₄ and other reaction gases N₂, NH₃, N₂O flow into the chamber at a same time without the bypass of the gas SiH₄, the abnormal reaction of the gas NH₃ caused by the supply of gas SiH₄ after the application of the RF power can be prevented.

While the present invention is described herein with reference to illustrative embodiments for particular applications, it should be understood that the present invention is not limited thereto. Those having ordinary skill in the art and access to the teachings provided herein will recognize additional modifications, applications, and embodiments within the scope thereof and additional fields in which the invention would be significant utility without undue experimentation.

### BRIEF DESCRIPTION OF THE DRAWINGS

The foregoing and other objects, aspects and advantages will be described with reference to the drawings, in which:

FIG. 1 is a graph illustrating a method of forming PE-SiON film for ARC according to the conventional art; and

FIG. 2 is a graph illustrating a method of forming a PE-SiON film for ARC according to the present invention.

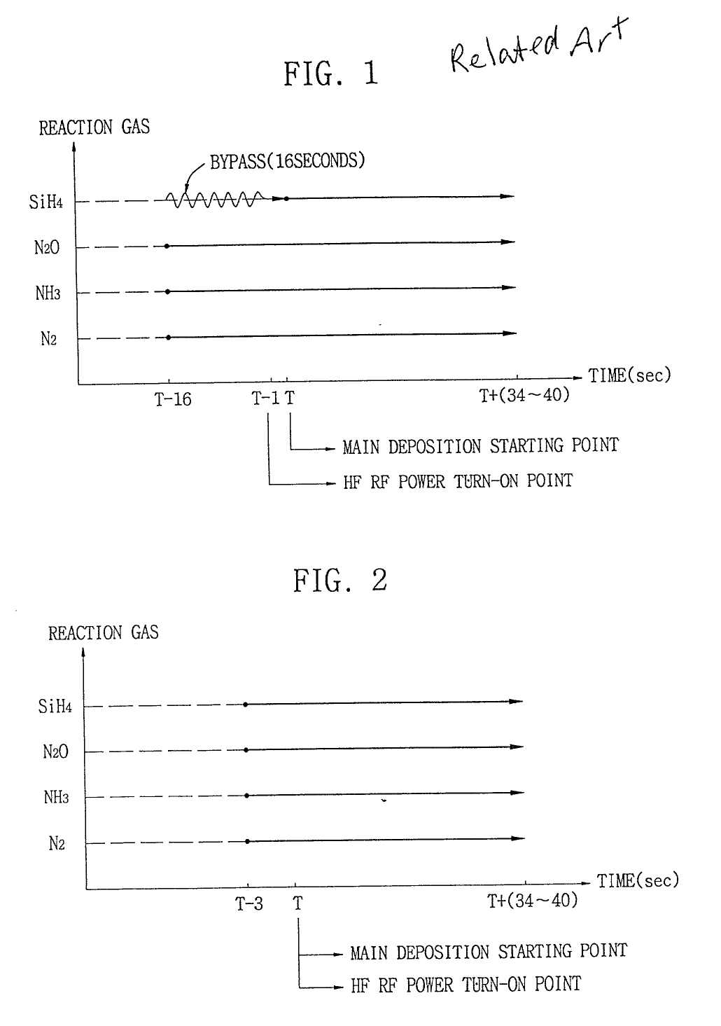

### DETAILED DESCRIPTION OF EMBODIMENTS

Hereinafter, an embodiment of the present invention is now explained in detail with reference to the accompanying drawings.

FIG. 2 is a graph illustrating the method of fabricating the PE-SiON film for ARC according to the present invention. In the drawing, the horizontal axis indicates time in second, and vertical axis indicates the reaction gases flowing into a chamber, and reference symbol T indicates the starting point at which a main deposition method of forming PE-SiON film starts.

The graph shown in FIG. 2 explains the deposition method of the PE-SiON film as follows. All the reaction gases N₂, NH₃, N₂O and the gas SiH₄ flow into the chamber at a same time, e.g., three seconds before the main deposition starting point T indicated as “T—3”. When high frequency radio frequency (HF RF) is supplied to the chamber after three seconds, the main deposition process for forming the PE-SiON film starts at the turn-on point T. That is, the starting point at which the main deposition process starts is identical to the point at which the HF RF power is turned-on.

The main deposition is performed during “T+(34˜40)” seconds from the point T. As a result, the PE-SiON film is formed. The chemical formula is identical to the chemical formula (1).

When the PE-SiON film is formed in such a way, since the RF power is turned-on under the state that the gas SiH₄ and other reaction gases N₂, NH₃, N₂O flow into the chamber at a same time without the bypass of SiH₄, the abnormal reaction of the gas NH₃, caused by the supply of gas SiH₄ after the application of the RF power, can be prevented, and the generation of particles is minimized.

As a result, defects in subsequent processing, such as the generation of bridge between the conductive patterns and defect in pattern, can be prevented.

According to the present invention as described in the above, the gas SiH₄ and the other reaction gases N₂, NH₃, N₂O flow into the chamber at a same time before the RF power is turned-on, without the bypass process of the gas SiH₄, thereby forming the PESiON film by chemical vapor deposition process. As a result, the abnormal reaction of NH₃ in the chamber can be prevented thereby minimizing the generation of particles during the formation of the PE-SiON film.

While the present invention is described herein with reference to illustrative embodiments for particular applications, it should be understood that the present invention is not limited thereto. Those having ordinary skill in the art and access to the teachings provided herein will recognize additional modifications, applications, and embodiments within the scope thereof and additional fields in which the invention would be of significant utility without undue experimentation.

What is claimed is:

1. A method of forming a PE-SiON film comprising:
simultaneously flowing a plurality of reaction gases SiH₄, N₂, NH₃, N₂O into a chamber; and
turning on a high frequency radio frequency power after some of said simultaneous flowing.

2. The method as defined in claim 1, wherein the high frequency radio frequency power is turned-on three seconds after said simultaneously flowing the plurality of reaction gases.

3. The method as defined in claim 1, wherein a depository of the PE-SiON film is performed during 34 to 40 seconds after said turning on.

4. The method of claim 1, wherein said simultaneous flowing is coextensive for all of the plurality of reaction gases.

5. The method as defined in claim 1, wherein said turning on starts a main deposition of the PE-SiON film.

6. A PE-SiON film formed by the method of claim 1.
